(19) United States
(12) Patent Application Publication
(10) Pub. No.: US 2023/0336141 A1
(43) Pub. Date: Oct. 19, 2023

(54) ACOUSTIC WAVE DEVICE

(71) Applicant: Murata Manufacturing Co., Ltd., Nagaokakyo-shi (JP)

(72) Inventors: Tetsuya KIMURA, Nagaokakyo-shi (JP); Ventsislav YANTCHEV, Sofia (BG); Patrick TURNER, Portola Valley, CA (US); Robert B. HAMMOND, Rockville, MD (US); Viktor PLESSKI, Gorgier (CH); Soumya YANDRAPALLI, Lausanne (CH); Bryant GARCIA, Austin, TX (US); Jesson JOHN, Dublin, CA (US)

(21) Appl. No.: 18/340,481

(22) Filed: Jun. 23, 2023

Related U.S. Application Data
(63) Continuation of application No. PCT/US21/65046, filed on Dec. 23, 2021.
(60) Provisional application No. 63/129,702, filed on Dec. 23, 2020.

(51) Int. Cl. H03H 9/02; H03H 9/17; H03H 9/13

(52) U.S. Cl. CPC H03H 9/02157; H03H 9/02102; H03H 9/173; H03H 9/132; H03H 9/02015

(57) ABSTRACT

An acoustic wave device is provided that includes a cavity in a substrate, an overlapping region in which portions of adjacent first and second interdigitated electrodes oppose each other, a first gap region between a first busbar and the overlapping region and that includes the first interdigitated electrodes but not the second interdigitated electrodes, and a second gap region between a second busbar and the overlapping region and that includes the second interdigitated electrodes but not the first interdigitated electrodes. A ratio d/p is about 0.5 or less, where d is a thickness of the piezoelectric layer and p is a distance between centers of adjacent first and second interdigitated electrodes. A first wall of the cavity is located under the first busbar or the first gap region, and a second wall of the cavity is located under the second busbar or the second gap region.

### CROSS REFERENCE TO RELATED APPLICATIONS

This application is a continuation of PCT/US2021/065046, filed Dec. 23, 2021, and claims the benefit of priority to U.S. Provisional Application No. 63/129,702 filed on Dec. 23, 2020. The entire contents of each application are hereby incorporated herein by reference.

### TECHNICAL FIELD

The present invention relates to acoustic wave devices each including a piezoelectric layer of lithium niobate or lithium tantalate.

### BACKGROUND

In known acoustic wave devices, heat radiation characteristics easily deteriorate. In particular, heat tends to stagnate in a cavity of an acoustic wave device, and heat radiation characteristics can be poor in acoustic wave devices with such cavities. FIG. 12 is a heat map of an acoustic wave device 100 without a cavity 109, and FIG. 13 is a heat map of an acoustic wave device 100 with a cavity 109. As shown in FIG. 13, heat can stagnate in the cavity 109. FIG. 14 shows the relationship between maximum temperature and normalized input power. In the acoustic wave device 100 without a cavity 109, the maximum temperature is constant or substantially constant. But in the acoustic wave device 100 with the cavity 109, the maximum temperature increases with increased temperature.

### SUMMARY OF THE INVENTION

In exemplary embodiments, acoustic wave devices are provided in which cavity walls are positioned to improve heat radiation characteristics.

According to an exemplary embodiment, an acoustic wave device is provided that includes a support, a piezoelectric layer on the support, and an interdigital transducer electrode on the piezoelectric layer and including a pair of busbars that are opposed to each other and a plurality of electrode fingers. A ratio d/p is about 0.5 or less, where d is a thickness of the piezoelectric layer and p is a distance between centers of adjacent electrode fingers of the plurality of electrode fingers. A cavity is provided in the support that faces the piezoelectric layer. The plurality of electrode fingers define an electrode finger extending direction in which the plurality of electrode fingers extend. An outer periphery of the cavity includes a pair of walls opposed to the electrode finger extending direction in a plan view thereof. Each of the pair of busbars includes an inner edge located on an inner side in the electrode finger extending direction. The interdigital transducer electrode has an overlapping region in which the plurality of electrode fingers overlap each other when viewed in a direction in which the adjacent electrode fingers are opposed, and a pair of gap regions that are each located between the overlapping region and a corresponding one of the pair of busbars. In the plan view, the pair of walls of the cavity overlaps an outer side portion outside the overlapping region in the electrode finger extending direction. An equation 0<L<Lb is satisfied for each of the pair of walls, where Lc is a dimension of the overlapping region along the electrode finger extending direction, Lb is a dimension of each of the pair of busbars in the electrode finger extending direction, and in the plan view, L is a location of each of the pair of walls of the cavity in the electrode finger extending direction, where a corresponding location of each inner edge of the pair of busbars in the electrode finger extending direction is a zero reference such that an outward direction of the interdigital transducer electrode is a positive direction and such that an inward direction of the interdigital transducer electrode is a negative direction.

In an exemplary aspect, the equation 0<L<(8/25)×Lc in each of the pair of walls is satisfied.

Moreover, the support can include a support substrate and an electrically insulating layer provided between the support substrate and the piezoelectric layer. The cavity can be provided in the electrically insulating layer, for example. The support can include a support substrate, and the cavity can be in the support substrate. In an exemplary aspect, the ratio d/p is less than or equal to about 0.24. An equation MR≤1.75(d/p)+0.075 can be satisfied, where MR is a metallization ratio of an area of the plurality of electrode fingers within the overlapping region to a total area of the overlapping region.

According to an exemplary embodiment, an acoustic wave device is provided that includes a support including a cavity with a first wall and a second wall that are opposed to each other; a piezoelectric layer on the support; an interdigital transducer electrode on the piezoelectric layer and including a first busbar including a first inner edge, first electrodes extending from the first inner edge, each of the first electrodes includes a first non-overlapping portion connected to the first inner edge and a first overlapping portion connected to the first non-overlapping portion; a second busbar including a second inner edge facing the first inner edge; and second electrodes extending from the second inner edge, each of the second electrodes includes a second non-overlapping portion connected to the second inner edge and a second overlapping portion connected to the non-overlapping portion and opposed to a corresponding first overlapping portion. In this aspect, a ratio d/p is about 0.5 or less, where d is a thickness of the piezoelectric layer and p is a distance between centers of adjacent electrode of the first and the second electrodes. The first wall of the cavity is located under the first busbar or the first non-overlapping portion of each of the first electrodes. The second wall of the cavity is located under the second busbar or the second non-overlapping portion of each of the second electrodes.

In an exemplary aspect, 0<L1<(8/25)×Lc is satisfied, where Lc is a length of the first overlapping portion of each of the first electrodes and the second overlapping portion of each of the second electrodes, and L1 is a distance from the first inner edge to the first wall. Moreover, 0<L2<(8/25)×Lc is satisfied, where L2 is a distance from the second inner edge to the second wall.

In an exemplary aspect, L1>(1/25)×Lc is satisfied, where Lc is a length of the first overlapping portion of each of the first electrodes and the second overlapping portion of each of the second electrodes, and L1 is a distance from the first inner edge to the first wall. Furthermore, L2>(1/25)×Lc is satisfied, where L2 is a distance from the second inner edge to the second wall.

According to an exemplary embodiment, an acoustic wave device is provided that includes a support, a cavity in the support and including a first wall and a second wall that are opposed to each other, a piezoelectric layer on the support, a first busbar including first electrodes extending from a first inner edge, a second busbar including second electrodes that extend from a second inner edge and that are interdigitated with the first electrodes, an overlapping region in which portions of adjacent first and second electrodes oppose each other, a first gap region that is adjacent to and in between the first busbar and the overlap region and that includes the first electrodes but not the second electrodes, and a second gap region that is adjacent to and in between the second busbar and the overlapping region and that includes the second electrodes but not the first electrodes. In this aspect, a ratio d/p is about 0.5 or less, where d is a thickness of the piezoelectric layer and p is a distance between centers of adjacent electrodes of the first and the second electrodes. The first wall of the cavity is located under the first busbar or the first gap region. The second wall of the cavity is located under the second busbar or the second gap region.

In an exemplary aspect, 0<L1<(8/25)×Lc is satisfied, where Lc is a width of the overlapping region, and L2 is a distance from the first inner edge to the first wall. An equation 0<L2<(8/25)×Lc can be satisfied, where L2 is a distance from the second inner edge to the second wall.

In another exemplary aspect, L1>(1/25)×Lc is satisfied, where Lc is a width of the overlapping region, and L1 is a distance from the first inner edge to the first wall. Moreover, L2 >(1/25)×Lc is satisfied, where L2 is a distance from the second inner edge to the second wall.

In an exemplary aspect, the support includes a support substrate and an electrically insulating layer provided between the support substrate and the piezoelectric layer, and the cavity can be provided in the electrically insulating layer. The support can also include a support substrate, and the cavity can be provided in the support substrate. The ratio d/p can be less than or equal to about 0.24. An equation MR≤1.75(d/p)+0.075 can be satisfied, where MR is a metallization ratio of an area of the first and the second electrodes within the overlapping region to a total area of the overlapping region.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a schematic perspective view showing an acoustic wave device according to a first exemplary embodiment.

FIG. 1B is a plan view showing an electrode structure on a piezoelectric layer.

FIG. 2 is a cross-sectional view taken along the line A-A in FIG. 1A.

FIG. 3A is a schematic elevational cross-sectional view that shows a Lamb wave propagating in a piezoelectric film of an acoustic wave device.

FIG. 3B is a cross-sectional view that shows a bulk wave propagating in a piezoelectric film of an acoustic wave device.

FIG. 4 schematically shows a bulk wave when a voltage is applied across the electrodes of an acoustic wave device.

FIG. 5 is a graph showing the resonant characteristics of the acoustic wave device according to the first exemplary embodiment.

FIG. 6 is a graph showing the relationship between the ratio d/p and the fractional bandwidth of the acoustic wave device as a resonator.

FIG. 7 is a plan view of an acoustic wave device according to a second exemplary embodiment.

FIG. 8 is a reference graph showing an example of the resonant characteristics of the acoustic wave device according to an exemplary embodiment.

FIG. 9 is a graph showing the relationship between a fractional bandwidth and the magnitude of normalized spurious for a large number of acoustic wave resonators.

FIG. 10 is a graph showing the relationship among the ratio d/2p, the metallization ratio MR, and the fractional bandwidth.

FIG. 11 is a diagram showing a map of a fractional bandwidth of the Euler angles (0°, θ, ψ) of LiNbO₃ when the ratio d/p is brought close to zero without limit.

FIG. 12 is a heat map of an acoustic wave device without a cavity.

FIG. 13 is a heat map of an acoustic wave device with a cavity.

FIG. 14 is a graph showing the relationship between the maximum temperature and the normalized input power of the acoustic wave devices of FIGS. 12 and 13.

FIGS. 15 and 16 show an acoustic wave device according to a first exemplary embodiment in which a cavity of the acoustic wave device overlaps with busbars of the acoustic wave device.

FIG. 17 shows an acoustic wave device according to a second exemplary embodiment in which a cavity of the acoustic wave device does not overlap with busbars of the acoustic wave device.

FIGS. 18-20 are cross-sectional views of acoustic wave devices with different arrangements of an electrically insulating layer according to exemplary aspects.

FIG. 21 shows an offset between outer peripheries of a cavity and inner edges of bulbar of an acoustic wave device.

FIG. 22 is a graph showing a relationship between the offset and the maximum temperature of the acoustic wave device of FIG. 21.

FIG. 23 shows an acoustic wave device with a cavity having an outer periphery that is not a straight line.

### DETAILED DESCRIPTION

In general, exemplary embodiments of the present invention include a piezoelectric layer 2 made of lithium niobate or lithium tantalate, and first and second electrodes 3, 4 opposed in a direction that intersects with a thickness direction of the piezoelectric layer 2.

Upon excitation of the first and second electrode 3 and 4, a bulk wave in a first thickness-shear mode is used. In addition, the first and the second electrodes 3, 4 can be adjacent electrodes, and, when a thickness of the piezoelectric layer 2 is d and a distance between a center of the first electrode 3 and a center of the second electrode 4 is p, a ratio d/p can be less than or equal to about 0.5, for example. It is noted that the term “about” 0.5 takes into account minor variances due to manufacturing variables, for example. With this configuration, the size of the acoustic wave device can be reduced, and the Q value or quality factor can be increased.

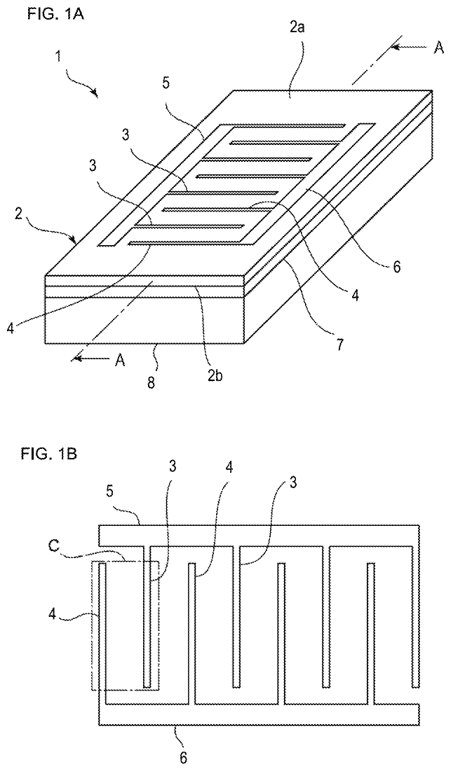

According to an exemplary aspect, an acoustic wave device 1 includes a piezoelectric layer 2 made of LiNbO₃. The piezoelectric layer 2 can also be made of LiTaO₃. The cut angle of LiNbO₃ or LiTaO₃ can be Z-cut and can be rotated Y-cut or X-cut. A propagation direction of Y propagation or X propagation of about ±30° can be used, for example. The thickness of the piezoelectric layer 2 is not limited and can be greater than or equal to about 50 nm and can be less than or equal to about 1000 nm, for example, to effectively excite a first thickness-shear mode. The piezoelectric layer 2 has opposed first and second major surfaces 2a, 2b. The electrodes 3, 4 are provided on the first major surface 2a. For purposes of this disclosure, the electrodes 3 are examples of the “first electrode” and can be referred to as “a plurality of first electrode fingers,” and the electrodes 4 are examples of the “second electrode” and can be referred to as “a plurality of second electrode fingers.” In FIG. 1A and FIGS. 1B, the plurality of electrodes 3 is connected to a first busbar 5, and the plurality of electrodes 4 is connected to a second busbar 6. The electrodes 3, 4 can be interdigitated with each other. The electrodes 3, 4 each can have a rectangular shape and can have a length direction. In a direction perpendicular to the length direction, each of the electrodes 3 and an adjacent one of the electrodes 4 are opposed to each other. In general, an IDT (interdigital transducer) electrode can be defined by the electrodes 3, 4, the first busbar 5, and the second busbar 6. The length direction of the electrodes 3, 4 and the direction perpendicular to the length direction of the electrodes 3, 4 both are directions that intersect with a thickness direction of the piezoelectric layer 2. For this reason, each of the electrodes 3 and the adjacent one of the electrodes 4 can be regarded as being opposed to each other in the direction that intersects with the thickness direction of the piezoelectric layer 2. Alternatively, the length direction of the electrodes 3, 4 can be interchanged with the direction perpendicular to the length direction of the electrodes 3, 4, shown in FIGS. 1A and 1B. In other words, in FIGS. 1A and 1B, the electrodes 3, 4 can be extended in a direction in which the first busbar 5 and the second busbar 6 extend. In this case, the first busbar 5 and the second busbar 6 extend in the direction in which the electrodes 3, 4 extend in FIGS. 1A and 1B. Pairs of adjacent electrodes 3 connected to one potential and electrodes 4 connected to the other potential are provided in the direction perpendicular to the length direction of the electrodes 3, 4. A state where the electrodes 3, 4 are adjacent to each other does not mean that the electrodes 3, 4 are in direct contact with each other and instead means that the electrodes 3, 4 are disposed via a gap between each other. When the electrodes 3, 4 are adjacent to each other, no electrode connected to a hot electrode or a ground electrode, including the other electrodes 3, 4, is disposed between the electrodes 3, 4.

The number of the pairs of electrodes 3, 4 is not necessarily an integer number of pairs and can be 1.5 pairs, 2.5 pairs, or the like in alternative aspects. For example, 1.5 pairs of electrodes means that there are three electrodes 3, 4, two of which is in a pair of electrodes and one of which is not in a pair. A distance between the centers of the electrodes 3, 4 (i.e., at least a pair of the electrodes), that is, the pitch of the electrodes 3, 4, can fall within the range of greater than or equal to about 1 μm and less than or equal to about 10 μm, for example. A distance between the centers of the electrodes 3, 4 can be a distance between the center of the width dimension of the electrodes 3, 4 in the direction perpendicular to the length direction of the electrodes 3, 4. In addition, when there is more than one electrode 3, 4 (e.g., when the number of electrodes 3, 4 is two such that the electrodes 3, 4 define an electrode pair, or when the number of electrodes 3, 4 is three or more such that electrodes 3, 4 define 1.5 or more electrode pairs), a distance between the centers of the electrodes 3, 4 means an average of a distance between any adjacent electrodes 3, 4 of the 1.5 or more electrode pairs. The width of each of the electrodes 3, 4, that is, the dimension of each of the electrodes 3, 4 in the opposed direction that is perpendicular to the length direction, can fall within the range of greater than or equal to about 150 nm and less than or equal to about 1000 nm, for example. A distance between the centers of the electrodes 3, 4 can be a distance between the center of the dimension of the electrode 3 in the direction perpendicular to the length direction of the electrode 3 (width dimension) and the center of the dimension of the electrode 4 in the direction perpendicular to the length direction of the electrode 4 (width dimension).

Because the Z-cut piezoelectric layer can be used, the direction perpendicular to the length direction of the electrodes 3, 4 is a direction perpendicular to a polarization direction of the piezoelectric layer 2. When a piezoelectric body with another cut angle is used as the piezoelectric layer 2, this does not apply. For purposes of this disclosure, the term “perpendicular” is not limited only to a strictly perpendicular case and can be substantially perpendicular (i.e., an angle formed between the direction perpendicular to the length direction of the electrodes 3, 4 and the polarization direction can be, for example, about 90°±10°).

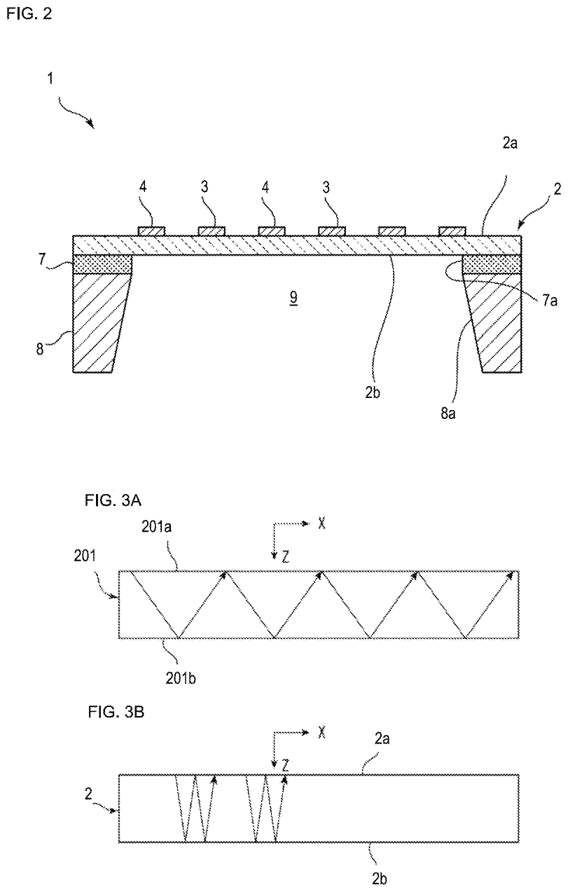

A support substrate 8 can be laminated via an electrically insulating layer or dielectric film 7 to the second major surface 2b of the piezoelectric layer 2. As shown in FIG. 2, the electrically insulating layer 7 can have a frame shape and can include an opening 7a, and the support substrate 8 can have a frame shape and can include an opening 8a. With this configuration, a cavity 9 can be formed. In exemplary aspects, the cavity 9 can extend in both the electrically insulating layer 7 and the support substrate 8. In an alternative aspect, the cavity 9 can extend only in the electrically insulating layer 7 (or a portion thereof), but not the support substrate 8. Moreover, the cavity 9 can be provided so as not to impede vibrations of an excitation region C of the piezoelectric layer 2. Therefore, the support substrate 8 can be laminated to the second major surface 2b via the electrically insulating layer 7 at a location that does not overlap a portion where at least one electrode pair is provided. The electrically insulating layer 7 does not need to be provided. Therefore, the support substrate 8 can be laminated directly or indirectly on the second major surface 2b of the piezoelectric layer 2. Although electrodes 3, 4 are shown to be on the first major surface 2a of the piezoelectric layer 2 that is opposite the cavity 9, in an alternative aspect, electrodes 3, 4 can be disposed on the second major surface 2b of the piezoelectric layer 2 and/or both the first and second major surfaces 2a and 2b.

The electrically insulating layer 7 can be made of silicon oxide. Other than silicon oxide, an appropriate electrically insulating material, such as silicon oxynitride, silicon dioxide and alumina, can also be used. The support substrate 8 can be made of Si or other suitable material. A plane direction of the Si can be (100) or (110) or (111). High-resistance Si with a resistivity higher than or equal to about 4 kΩ, for example, can be used. The support substrate 8 can also be made of an appropriate electrically insulating material or an appropriate semiconductor material. Examples of the material of the support substrate 8 include a piezoelectric body, such as aluminum oxide, lithium tantalate, lithium niobate, and quartz crystal; various ceramics, such as alumina, magnesia, sapphire, silicon nitride, aluminum nitride, silicon carbide, zirconia, cordierite, mullite, steatite, and forsterite; a dielectric, such as diamond and glass; and a semiconductor, such as gallium nitride.

In the exemplary aspect, the first and the second electrodes 3, 4 and the first and the second busbars 5, 6 can be made of an appropriate metal or alloy, such as Al and AlCu alloy. The first and the second electrodes 3, 4 and the first and the second busbars 5, 6 can include a structure such as an Al film that can be laminated on a Ti film. An adhesion layer other than a Ti film can be used.

In operation, to drive the acoustic wave device 1, an alternating-current voltage is applied between the first and the second electrodes 3, 4. More specifically, an alternating-current voltage is applied between the first and the second bulbar 5, 6 to excite a bulk wave in a first thickness-shear mode in the piezoelectric layer 2. In the acoustic wave device 1, when the thickness of the piezoelectric layer 2 is d and a distance between the centers of adjacent first and second electrodes 3, 4 of the electrode pairs is p, the ratio d/p can be less than or equal to about 0.5, for example. For this reason, a bulk wave in the first thickness-shear mode can be effectively excited, which results in good resonant characteristics being obtained. The ratio d/p can less than or equal to about 0.24, and, in this case, further good resonant characteristics can be obtained. When there is more than one electrode, the distance p between the centers of the adjacent electrodes 3, 4 is an average distance of the distance between the centers of any adjacent electrodes 3, 4.

With the above configuration, the Q value or quality factor of the acoustic wave device 1 is unlikely to decrease, even when the number of electrode pairs is reduced for size reduction. The Q value is unlikely to decrease if the number of electrode pairs is reduced because the acoustic wave device 1 is a resonator that needs no reflectors on both sides, and therefore, a propagation loss is small. No reflectors are needed because a bulk wave in a first thickness-shear mode is used.

The difference between a Lamb wave used in known acoustic wave devices and a bulk wave in the first thickness-shear mode is described with reference to FIGS. 3A and 3B.

FIG. 3A is a schematic elevational cross-sectional view for illustrating a Lamb wave propagating in a piezoelectric film of an acoustic wave device as described in Japanese Unexamined Patent Application Publication No. 2012-257019.

As shown, the wave propagates in a piezoelectric film 201 as indicated by the arrows in FIG. 3A. In the piezoelectric film 201, a first major surface 201a and a second major surface 201b are opposed to each other, and a thickness direction connecting the first major surface 201a and the second major surface 201b is a Z direction. An X direction is a direction in which electrode fingers of an interdigital transducer electrode are arranged. As shown in FIG. 3A, a Lamb wave propagates in the X direction. The Lamb wave is a plate wave, so the piezoelectric film 201 vibrates as a whole. However, the wave propagates in the X direction. Therefore, resonant characteristics are obtained by arranging reflectors on both sides. For this reason, a wave propagation loss occurs, and the Q value or quality factor decreases when the size is reduced, that is, when the number of electrode pairs is reduced.

In contrast, as shown in FIG. 3B, in the acoustic wave device 1 of the exemplary aspect, a vibration displacement is caused in the thickness-shear direction, so the wave propagates substantially in the direction connecting the first and the second major surfaces 2a, 2b of the piezoelectric layer 2, that is, the Z direction, and resonates. In other words, the X-direction component of the wave is significantly smaller than the Z-direction component. Since the resonant characteristics are obtained from the propagation of the wave in the Z direction, no reflectors are needed. Thus, there is no propagation loss caused when the wave propagates to reflectors. Therefore, even when the number of electrode pairs is reduced to reduce size, the Q value or quality factor is unlikely to decrease.

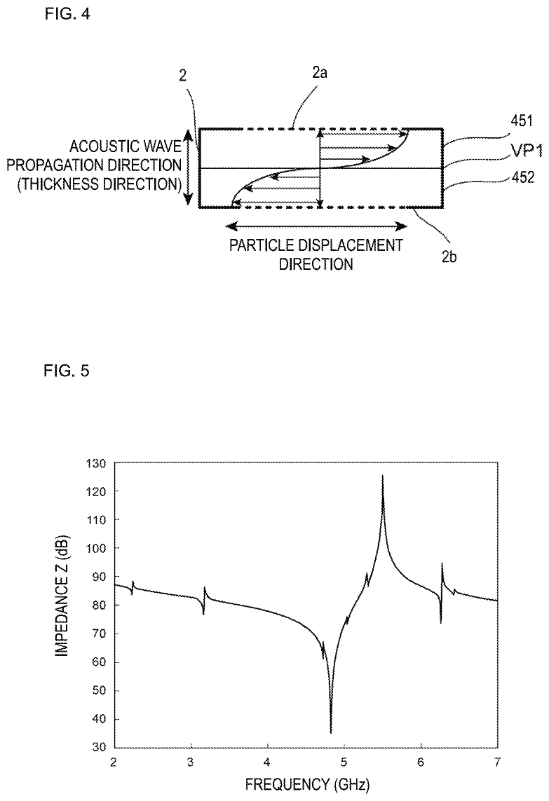

As shown in FIG. 4, the amplitude direction of the bulk wave in the first thickness-shear mode is opposite in a first region 451 included in the excitation region C of the piezoelectric layer 2 and a second region 452 included in the excitation region C, where the excitation region C is shown in FIG. 1B. FIG. 4 schematically shows a bulk wave when a higher voltage is applied to the electrodes 4 than a voltage applied the electrodes 3. The first region 451 is a region in the excitation region C between the first major surface 2a and a virtual plane VP1 that is perpendicular to the thickness direction of the piezoelectric layer 2 and that divides the piezoelectric layer 2 into two. The second region 452 is a region in the excitation region C between the virtual plane VP1 and the second major surface 2b.

As described above, the acoustic wave device 1 includes at least one electrode pair. However, the wave is not propagated in the X direction, so the number of electrode pairs 4 does not necessarily need to be two or more. In other words, only one electrode pair can be provided.

For example, the first electrode 3 is an electrode connected to a hot potential, and the second electrode 4 is an electrode connected to a ground potential. Of course, the first electrode 3 can be connected to a ground potential, and the second electrode 4 can be connected to a hot potential. Each first or second electrode 3, 4 is connected to a hot potential or is connected to a ground potential as described above, and no floating electrode is provided.

FIG. 5 is a graph showing the resonant characteristics of the acoustic wave device 1. The design parameters of the acoustic wave device 1 having the resonant characteristics are as follows. In this example, the piezoelectric layer 2 is made of LiNbO₃ with Euler angles of (0°, 0°, 90°) and has a thickness of about 400 nm, for example. But, as explained above, the piezoelectric layer 2 can be LiTaO₃, and other suitable Euler angles and thicknesses can be used in alternative aspects.

When viewed in a direction perpendicular to the length direction of the first and the second electrodes 3, 4, the length of a region in which the first and the second electrodes 3, 4 overlap, that is, the excitation region C, can be about 40 μm, the number of electrode pairs of electrodes 3, 4 can be 21, the distance between the centers of the first and the second electrodes 3, 4 can be about 3 μm, the width of each of the first and the second electrodes 3, 4 can be about 500 nm, and the ratio d/p can be about 0.133, for example.

Moreover, the electrically insulating layer 7 can be made of a silicon oxide film having a thickness of about 1 μm, for example. The support substrate 8 can be made of Si. The length of the excitation region C can be along the length direction of the first and the second electrodes 3, 4. The distance between any adjacent electrodes of the electrode pairs can be equal or substantially equal within manufacturing and measurement tolerances among all of the electrode pairs. In other words, the first and the second electrodes 3, 4 can be disposed at a constant pitch.

As is apparent from FIG. 5, although no reflectors are provided, good resonant characteristics with a fractional bandwidth of about 12.5% can be obtained.

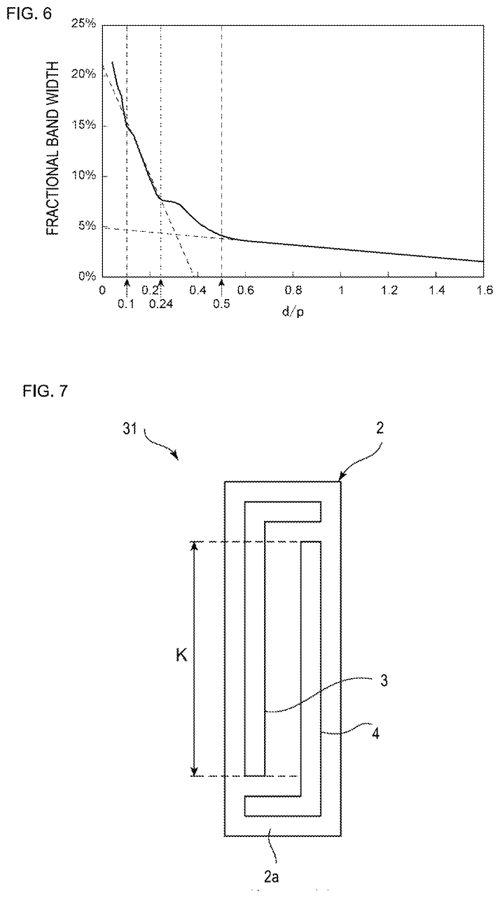

When the thickness of the piezoelectric layer 2 is d and the distance between the centers of the electrode pairs is p, the ratio d/p can be less than or equal to about 0.5 or can be less than or equal to about 0.24, for example. The ratio d/p will be further discussed with reference to FIG. 6 below.

Acoustic wave devices can be provided with different ratios d/p as in the case of the acoustic wave device having the resonant characteristics shown in FIG. 5. FIG. 6 is a graph showing the relationship between the ratio d/p and the fractional bandwidth when the acoustic wave device 1 is used as a resonator.

As is apparent from the non-limiting example shown in FIG. 6, when the ratio d/p >0.5, the fractional bandwidth is lower than about 5%, even when the ratio d/p is adjusted. In contrast, in the case where the ratio d/p ≤0.5, the ratio d/p changes within the range, and the fractional bandwidth can be set to about 5% or higher, that is, a resonator having a high coupling coefficient can be provided, for example. In the case where the ratio d/p is lower than or equal to about 0.24, the fractional bandwidth can be increased to about 7% or higher, for example. In addition, when the ratio d/p is adjusted within the range, a resonator having a further wide fractional bandwidth can be obtained, so a resonator having a further high coupling coefficient can be achieved. Therefore, it has been discovered and confirmed that, when the ratio d/p is set to about 0.5 or less, for example, a resonator that uses a bulk wave in the first thickness-shear mode with a high coupling coefficient can be provided.

As described above, at least one electrode pair can be one pair, and, in the case of one electrode pair, p is defined as the distance between the centers of the adjacent pair of the first and second electrodes 3, 4. In the case of 1.5 or more electrode pairs, an average distance of the distance between the centers of any adjacent electrodes 3, 4 can be defined as p.

For the thickness d of the piezoelectric layer 2, when the piezoelectric layer 2 has thickness variations, an averaged value of the thicknesses can be used.

FIG. 7 is a plan view of an acoustic wave device 31 according to a second exemplary embodiment. As shown in the acoustic wave device 31, one electrode pair including the first and the second electrodes 3, 4 is provided on the first major surface 2a of the piezoelectric layer 2. In FIG. 7, K is an overlap width. As described above, in the acoustic wave device 31, the number of electrode pairs of can be one. In this case as well, when the ratio d/p is less than or equal to about 0.5, for example, a bulk wave in a first thickness-shear mode can be effectively excited.

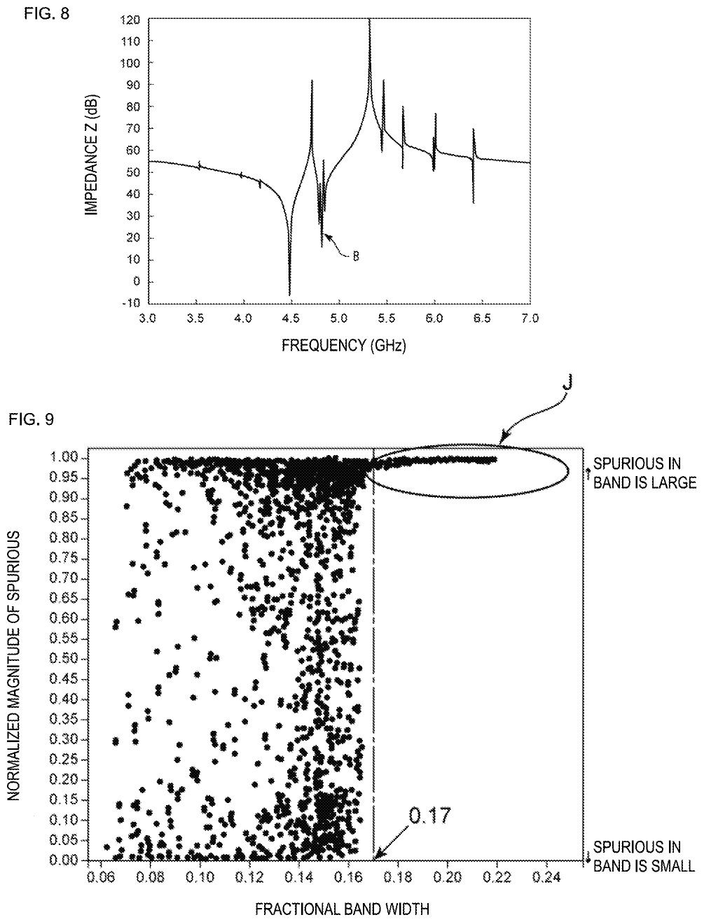

In the acoustic wave device 31, a metallization ratio MR of an area of any adjacent first and second electrodes 3, 4 within the excitation region C, i.e., a region in which any adjacent electrodes 3, 4 overlap when viewed in the opposed direction, to a total area of the excitation region C, can satisfy MR≤1.75 (d/p)+0.075, effectively reducing spurious occurrences. This reduction will be described with reference to FIGS. 8 and 9. FIG. 8 is a reference graph showing an example of the resonant characteristics of the acoustic wave device 31. The spurious occurrence indicated by the arrow B appears between a resonant frequency and an anti-resonant frequency. The ratio d/p can be set to about 0.08, and the Euler angles of LiNbO₃ can be set to (0°, 0°, 90°), for example. The metallization ratio MR can be set to about 0.35, for example.

The metallization ratio MR will be described with reference to FIG. 1B. In the electrode structure of FIG. 1B, when focusing on one electrode pair, it is assumed that only the one electrode pair is provided. In this case, the portion surrounded by the alternate long and short dashed line C is the excitation region. The excitation region C includes, when the first and the second electrodes 3, 4 are viewed in the direction perpendicular to the length direction of the first and the second electrodes 3, 4, that is, the opposed direction, a first region of the first electrode 3 overlapping with the second electrode 4, a second region of the second electrode 4 overlapping with the first electrode 3, and a third region in which the first and the second electrodes 3, 4 overlap in a region between the first and the second electrodes 3, 4. Then, the ratio of the area of the first and the second electrodes 3, 4 in the excitation region C to the area of the excitation region C is the metallization ratio MR. In other words, the metallization ratio MR is the ratio of the area of a metallization portion to the area of the excitation region C.

When a plurality of electrode pairs is provided, the ratio of a metallization portion included in the total excitation region to the total area of the excitation region is the metallization ratio MR. That is, the metallization ratio MR can be the ratio of an area of the first and the second electrodes 3, 4 within an overlapping region, i.e., a region in which the first and the second electrodes 3, 4 overlap each other, to a total area of the overlapping region.

FIG. 9 is a graph showing the relationship between a fractional bandwidth and a magnitude of normalized spurious for a large number of acoustic wave resonators in which a phase rotation amount of impedance of spurious is normalized by 180° as the magnitude of spurious. The phase rotation amount of impedance is an indicator of the magnitude of spurious, which is related to the impedance ratio. The impedance ratio relates to the difference between the minimum value and the maximum value of the impedance, while the phase rotation amount of impedance relates to the peak value of the impedance. For the fractional bandwidth, the film thickness of the piezoelectric layer 2 and the dimensions of the first and the second electrodes 3, 4 are variously changed and adjusted. FIG. 8 is graph showing the resonant characteristics when material of the piezoelectric layer 2 is Z-cut LiNbO₃, and similar resonant characteristics can be obtained when the material of the piezoelectric layer 2 uses another cut angle.

As illustrated in a region surrounded by the ellipse J in FIG. 9, the spurious is about 1.0 and large. As is apparent from FIG. 9, when the fractional bandwidth exceeds about 0.17, that is, about 17%, large spurious having a spurious level greater than or equal to one appears in a pass band, even when parameters of the fractional bandwidth are changed. In other words, as in the case of the resonant characteristics shown in FIG. 8, large spurious indicated by the arrow B appears in the pass band. Thus, the fractional bandwidth is preferably lower than or equal to about 17%, for example. In this case, spurious can be reduced by adjusting the film thickness of the piezoelectric layer 2, the dimensions of the first and the second electrodes 3, 4, and the like.

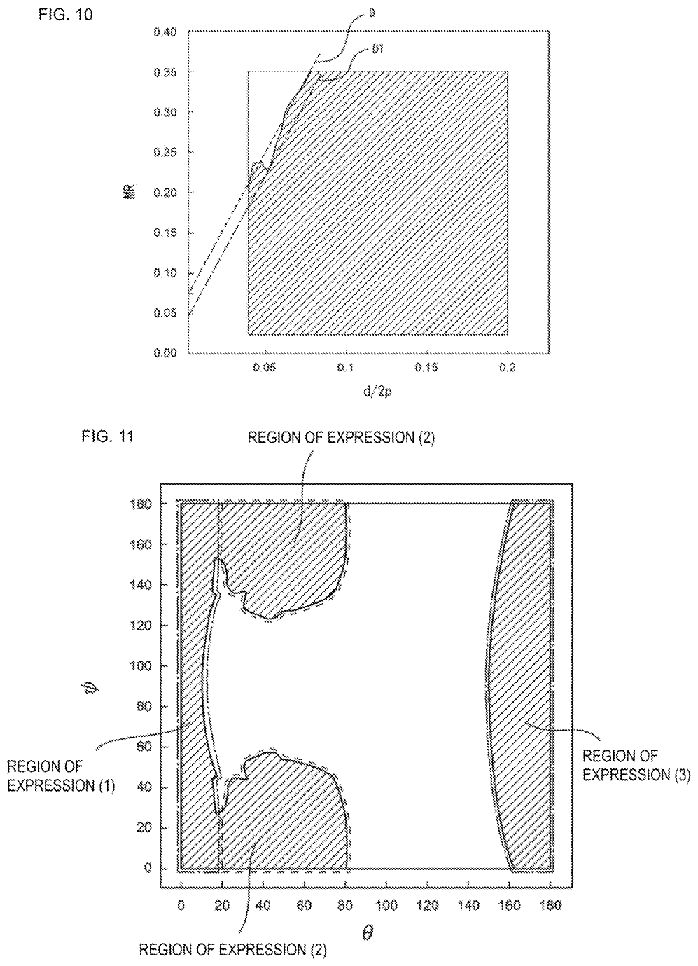

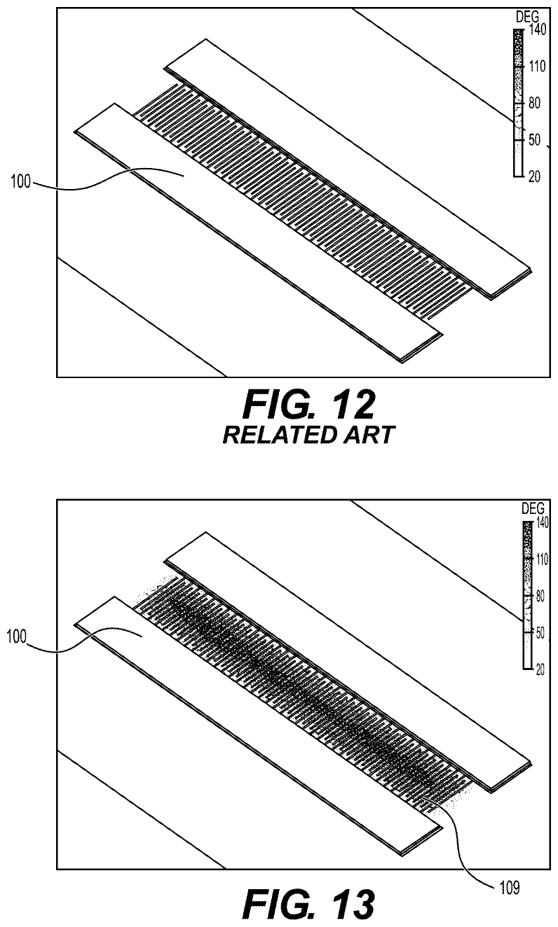

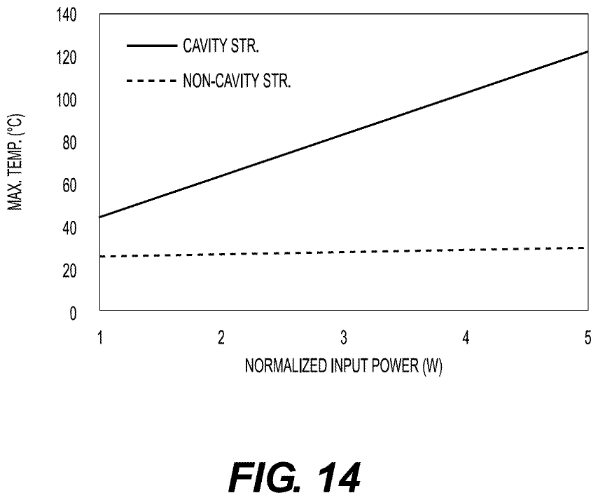

FIG. 10 is a graph showing the relationship among the ratio d/2p, the metallization ratio MR, and the fractional bandwidth. The fractional bandwidths of various acoustic wave devices with different ratios d/2p and with different metallization ratios MR are measured. The hatched portion on the right-hand side of the dashed line D in FIG. 10 is a region in which the fractional bandwidth is lower than or equal to about 17%, for example. The dashed line D between the hatched region and a non-hatched region is expressed by MR=3.5 (d/2p)+0.075=1.75 (d/p)+0.075. When the metallization ratio MR satisfies MR≤1.75 (d/p)+0.075, the fractional bandwidth can be set to about 17% or lower, for example. Additionally, FIG. 10 shows a long- and short-dashed line D1 expressed by MR=3.5 (d/2p)+0.05. When the metallization ratio MR satisfies MR≤1.75 (d/p)+0.05, the fractional bandwidth can be reliably set to about 17% or lower, for example.

FIG. 11 is a diagram showing a map of the fractional bandwidth for the Euler angles (0°, θ, ψ) of LiNbO₃ when the ratio d/p is brought close to zero without limit. The hatched portions in FIG. 11 are regions in which the fractional bandwidth is at least about 5% or higher, and the boundaries of the hatched portions are approximated by the following expressions (1), (2), and (3):

(0°±10°,0° to 20°,any ψ) (1)

(0°±10°,20° to 80°,0° to 60°(1−(θ−50)²/900)^{1/2}) or

(0°±10°,20° to 80°,[180°−60°(1−(θ−50)²/900)^{1/2}] to 180°) (2)

(0°±10°,[180°−30°(1−(ψ−90)²/8100)^{1/2}] to 180°,any ψ) (3)

Therefore, when the Euler anglers of the material used for the piezoelectric layer 2 of an acoustic wave resonator satisfy the above expressions (1), (2), and (3), the fractional bandwidth of the acoustic wave resonator can be sufficiently widened.

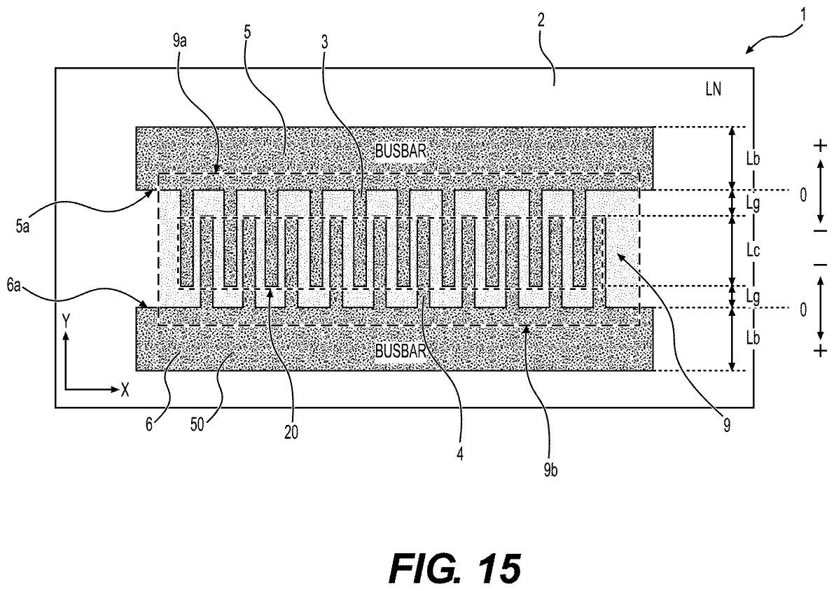

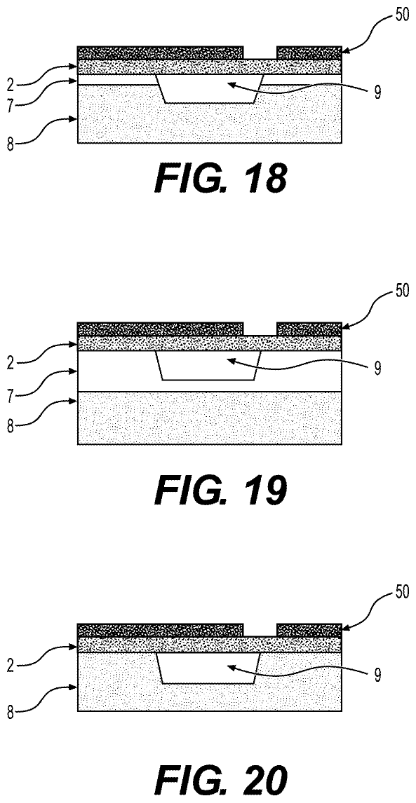

FIGS. 15-17 show acoustic wave devices 1 that include a piezoelectric layer 2 and an IDT electrode 50 on the piezoelectric layer 2. Although not shown in FIGS. 15-17, the acoustic wave devices 1 can include a support that is defined by a support substrate 8 (as shown in FIGS. 18-20) and an optional electrically insulating layer 7 (as shown in FIGS. 18 and 19). The IDT electrode 50 can at least partially overlap with a cavity in the support and can include a first busbar 5, first electrodes 3 connected to and extending from the first busbar 5, a second busbar 6, and second electrodes 4 connected to and extending from the second busbar 6. The first and the second electrodes 3, 4 can be interdigitated electrode fingers. FIGS. 15-17 show an outline of a cavity 9 with broken lines. The first busbar 5 can include a first inner edge 5a, and the second busbar 6 can include a second inner edge 5b. The first electrodes 3 can extend from the first inner edge 5a, and the second electrodes 4 can extend from the second inner edge 6a.

An overlap region 20 is a region in which portions of adjacent first and second electrodes 3, 4 overlap relative to the X direction with the electrodes 3, 4 extending in the Y direction. A first gap region 31 is the region including only portions of the first electrodes 3 between the first busbar 5 and the overlapping region 20, and a second gap region 32 is the region including only portions of the second electrodes 4 between the second busbar 6 and the overlapping region 20. Each of the first electrodes 3 can include a non-overlapping portion in the first gap region 31 that is connected to the first busbar 5 and can include an overlapping portion in the overlapping region 20 connected to the non-overlapping portion. Likewise, each of the second electrodes 4 can include a non-overlapping portion in the second gap region 31 that is connected to the second busbar 6 and can include an overlapping portion in the overlapping region 20 connected to the non-overlapping portion. The first and the second electrodes 3, 4 can be interdigitated such that adjacent overlapping portions of the first and the second electrodes 3, 4 oppose each other.

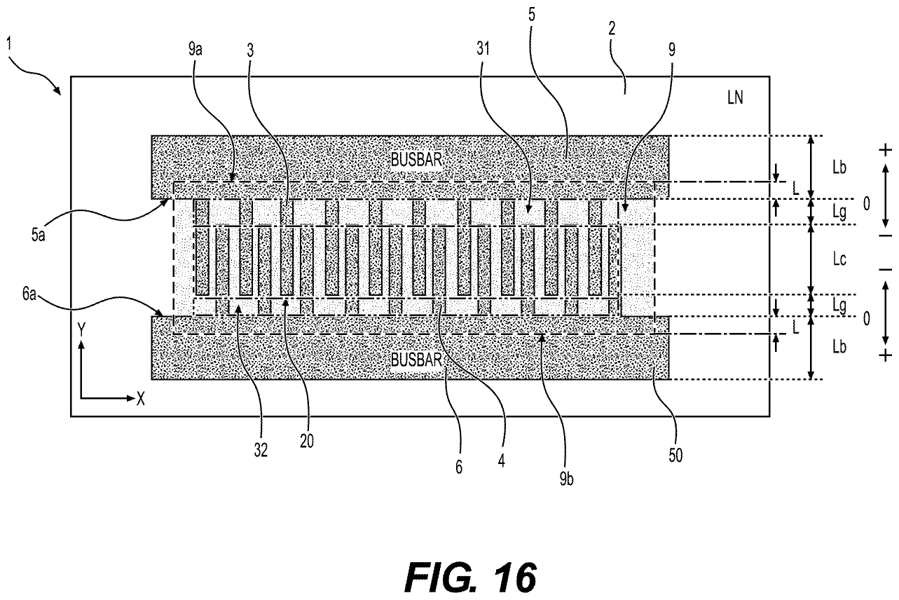

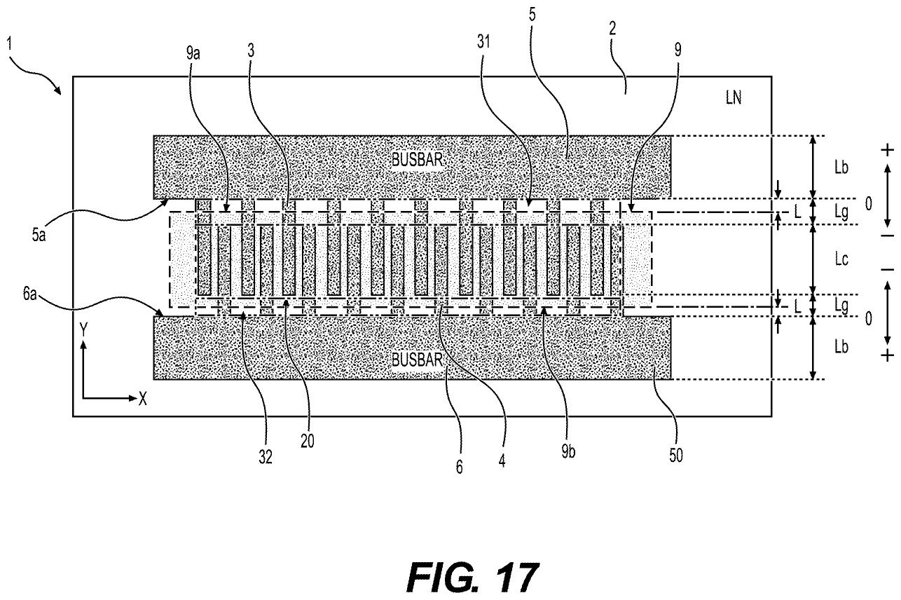

The cavity 9 can include a first wall or outer peripheral portion 9a and a second wall or outer peripheral portion 9b. As shown in FIGS. 15 and 16, the first wall 9a can be under the first busbar 5 and/or the second wall 9b can be under the second busbar 6, and as shown in FIG. 17, the first wall 9a can be under the first gap region 31 and/or the second wall 9b can be under the second gap region 32.

Lc can be a dimension of the overlapping region 20 along an electrode finger extending direction (i.e., the y-direction in FIGS. 15 and 16); Lg can be a dimension of each of the first and the second gap regions 31, 32 along the electrode finger extending direction; Lb can be a dimension of each of the first and the second busbars 5, 6 along the electrode finger extending direction; and in a plan view, an offset distance L can be a location of each of the first and the second walls 9a, 9b of the cavity 9 in the electrode finger extending direction (as shown in FIG. 16 but not FIG. 15) where a location of each of the first and the second inner edges 5a, 5b in the electrode finger extending direction can be considered a zero reference such that an outward direction of the IDT electrode 50 is a positive direction (i.e., in the positive y-direction in FIGS. 15-17) and such that an inward direction of the IDT electrode 50 is a negative direction (i.e., in the negative y-direction in FIGS. 15-17). FIGS. 15-17 shows the zero reference on the right side with the positive and negative directions labeled with arrows.

For example, Lc can be the length of the overlapping portion of the first and the second electrodes 3, 4 or can be the width of the overlapping region 20; Lg can be the length of the non-overlapping portion of the first and the second electrodes 3, 4 or can be the width of the non-overlapping regions 31, 32; offset distance L can be the distance from the first or the second inner edges 5a, 6a to the corresponding one of the first or the second walls 9a, 9b, where distances extending in the first and the second busbars 5, 6 are positive and where distances extending in the opposite direction (i.e., along the first or the second electrodes 3, 4) are negative.

As shown in FIGS. 15 and 16, the equation 0<L<Lb for each of the first and the second walls 9a, 9b can be satisfied.

According to an exemplary aspect, in the plan view, the first and the second walls 9a, 9b of the cavity 9 overlap an outer side portion outside the overlapping region 20 in the electrode finger extending direction. The overlapping region 20 is a region in which portions of the first and the second electrodes 3, 4 overlap each other when viewed in a direction in which adjacent electrodes 3, 4 are opposed. That is, as shown in FIGS. 15 and 16, the first wall 9a can be under the first busbar 5, and the second walls 9b can be under the second busbar 6.

In FIG. 16, an acoustic wave device 1 includes a support including a support substrate 8 (not shown in FIG. 16) and an optional electrically insulating layer 7 (not shown in FIG. 16), a piezoelectric layer 2 on the support substrate 8 via a cavity 9, and an IDT electrode 50 provided on the piezoelectric layer 2.

The IDT electrode 50 can include first and second busbars 5, 6 opposed to each other, a plurality of first electrodes 3 of which proximal ends are connected to the first busbar 5 and of which distal ends extend toward the second busbar 6, a plurality of second electrodes 4 of which proximal ends are connected to the second busbar 6 and of which distal ends extend toward the first busbar 5. The plurality of first electrodes 3 and the plurality of second electrodes 4 interdigitate with each other. At least a portion of the IDT electrode 50 overlaps the cavity 9 in the plan view in a thickness direction of the support substrate 8.

In the plan view in the thickness direction of the support substrate 8, first and second walls 9a, 9b of the cavity 9 are provided at outer side locations beyond the first and the second inner edges 5a, 6a of the first and the second busbars 5, 6. Of the outer portions or edges of the cavity 9 (i.e., of any of the walls of the cavity 9) in the electrode finger extending direction (i.e., the y-direction in FIG. 16), any one of a first busbar-side outer edge (first wall 9a) and a second busbar-side outer edge (second wall or second wall 9b) may be provided at a location beyond electrode finger-side outer edges (first and second inner edges 5a, 6a) of the first and the second busbars 5, 6. That is, the first wall 9a of the cavity 9 can be located under the first busbar 5, and the second wall 9b of the cavity 9 can be located under the second busbar 6.

In the IDT electrode 50, the first gap region 31 can be located between the overlapping region 20 and the first busbar 5, and the second gap region 32 can be located between the overlapping region 20 and the second busbar 5.

Lc can be the dimension along the electrode finger extending direction (i.e., the y-direction in FIG. 16) of the overlapping region 20; Lg can be the dimension along the electrode finger extending direction of each of the first and the second gap regions 31, 32; Lb can be the dimension along the electrode finger extending direction of each of the first and the second busbars 5, 6; and in the plan view, the offset distance L can be the location of each of the first and the second walls 9a, 9b of the cavity 9 in the electrode finger extending direction, where the location of each of the first and the second inner edges 5a, 5b is a zero reference such that the outward direction of the IDT electrode 50 is a positive direction (i.e., in the positive y-direction and such that the inward direction of the IDT electrode 50 is a negative direction (i.e., in the negative y-direction).

In FIG. 16, the equation 0<L<Lb is satisfied. That is, the first wall 9a of the cavity 9 is under the first busbar 5, and the second wall 9b of the cavity 9 is under the second busbar 6. Alternatively, both of the first and the second walls 9a, 9b do not have to be under one of the first and the second busbars 5, 6. That is, either the first wall 9a of the cavity 9 is under the first busbar 5, or the second wall 9b of the cavity 9 is under the second busbar 6.

In FIG. 17, in the plan view in the thickness direction of the support substrate 8 (the support substrate 8 not shown in FIG. 17), the first and the second walls 9a, 9b of the cavity 9 are provided at locations inside the first and the second inner edges 5a, 6a of the first and the second busbars 5, 6 and outside an envelope connecting distal ends of the pluralities of first and second electrodes 3, 4, i.e., the overlapping region 20. Of the first and the second walls 9a, 9b of the cavity 9, only any one of the first wall 9a and the second wall 9b may be provided at a location inside the first or the second inner edges 5a, 6a of the first and the second busbars 5, 6 and outside the envelope connecting the distal ends of the pluralities of the first and the second electrodes 3, 4 in the plan view. In other words, at least one of the first and the second walls 9a, 9b may overlap one of the first or the second gap regions 31 or 32.

In FIG. 17, the equation −Lg<L<0 is satisfied for the first and/or the second walls 9a, 9b of the cavity 9. That is, the first wall 9a of the cavity 9 can be located under the first gap region 31, and/or the second wall 9b of the cavity 9 can be located under the second gap region 32. Alternatively, the first wall 9a of the cavity 9 can be located under the non-overlapping portion of each of the first electrodes 3, and/or the second wall 9b of the cavity 9 can be located under the non-overlapping portion of each of the second electrodes 4.

FIGS. 18-20 illustrate different exemplary arrangements of the support, the electrically insulating layer 7, and the cavity 9. In particular, FIGS. 18 and 19 include the optional electrically insulating layer 7, but FIG. 20 does not include the optional electrically insulating layer 7. In FIG. 18, the cavity 9 extends through the electrically insulating layer 7 into the support substrate 8. In FIG. 19, the cavity 9 is provided only in the electrically insulating layer 7. As shown in FIG. 20, the support can only include the support substrate 8 and does not include the electrically insulating layer 7. In FIG. 20, the cavity 9 is in the support substrate 8. The arrangements shown in FIGS. 18-20 can be used with the different preferred embodiments of the present invention, including those shown in FIGS. 15-17.

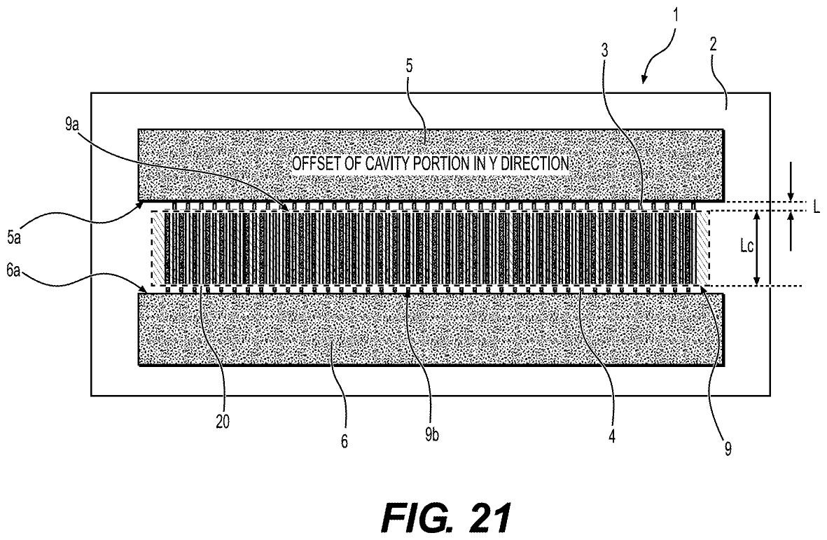

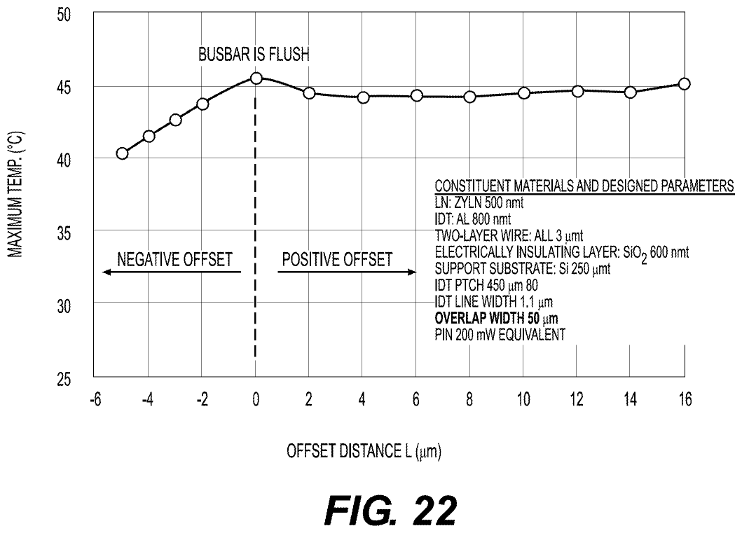

As shown in FIG. 21, where a distance between each of the first and the second walls 9a and 9b of the cavity 9 and a corresponding one of the first and the second inner edges 5a, 6a of the first and the second busbars 5, 6 in the plan view is an offset distance of the cavity 9 in a y-direction (electrode finger extending direction)(labeled as L in FIG. 21), and when the offset distance L is a positive value (i.e., when each of the first and the second walls 9a, 9b of the cavity 9 is located outside a corresponding one of the first and the second inner edges 5a, 6a of the first and the second busbars 5, 6 in the plan view), the temperature of a surface of the piezoelectric layer 2 can easily decrease, as compared to when the offset distance is zero (i.e., each of the first and the second walls 9a, 9b of the cavity 9 is the same or flush in the plan view with a corresponding one of the first and the second inner edges 5a, 6a of the first and the second busbars 5, 6). Thus, the heat radiation characteristics can be improved as shown in FIG. 22.

FIG. 22 shows a graph of the relationship between the maximum temperature and the offset distance L for a device with the following parameters:
LN: ZYLN 500 nmt
IDT: AL 500 nmt
TWO-LAYER WIRE: AL 3 μmt
ELECTRICALLY INSULATING LAYER: SiO₂ 600 nmt
SUPPORT SUBSTRATE: Si 250 μmt
IDT PITCH 4.55 μm, 80
IDT LINE WIDTH 1.1 μm
OVERLAP WIDTH 50 μm
Pin 200 mW EQUIVALENT
   When the first and the second walls 9a, 9b of the cavity 9 are under the first and the second busbars 5, 6, the offset distance L is a negative value (i.e., the offset distance L<0), and when the first and the second walls 9a, 9b of the cavity 9 are under the first and the second gap regions 31, 32, the offset distance is a positive value, (i.e., the offset distance L>0).

As shown in FIG. 22, when the offset distance L is, for example, a value less than or equal to −1/25 of an overlapping width Lc, heat radiation characteristics can be further remarkably improved, and when the offset distance L is, for example, a value less than or equal to +8/25 of the overlapping width Lc, the heat radiation characteristics can be improved as compared to when the offset distance L is zero. Thus, when −Lg<L<−(1/25)×Lc or 0<L<(8/25)×Lc, heat radiation characteristics can be effectively enhanced. Alternatively, the offset distances of the first and the second walls 9a, 9b can be different. That is, if offset distance L1 is the offset distance of the first walls 9a and if offset distance L2 is the offset distance of the second walls 9a, then:

−Lg<L1<−(1/25)×Lc or 0<L1<(8/25)×Lc; and

−Lg<L2<−(1/25)×Lc or 0<L2<(8/25)×Lc

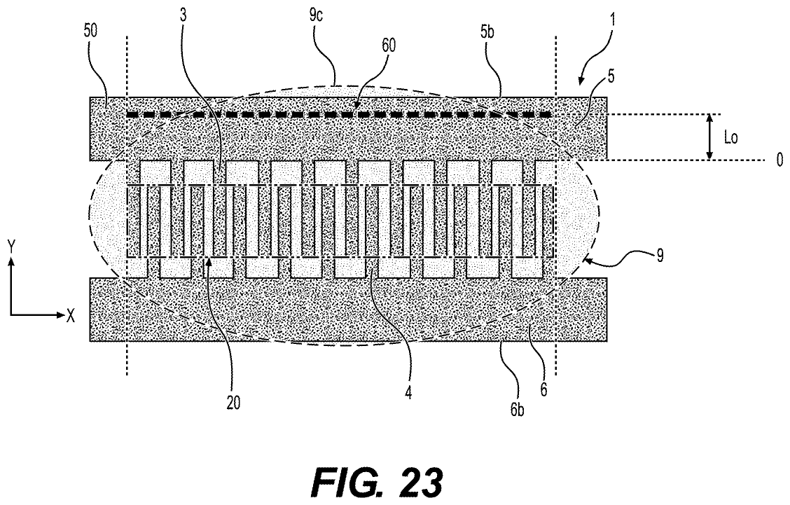

According to an exemplary aspect, FIG. 23 shows an acoustic wave device 1 that includes an IDT 50 and a cavity 9. As shown in FIG. 23, the cavity 9 does not include straight lines and can be curved, for example. Although not shown in FIG. 23, the IDT electrode 50 may be apodised in a rhombus shape.

The wall 9c of the cavity 9 or outer edges 5b, 6b of the first and the second busbars 5, 6 do not have to have a straight line shape. Instead, FIG. 23 shows the cavity 9 with a wall 9c that is curved. In this aspect, an average imaginary straight line 60 (e.g., a dashed horizontal line through first busbar 5) over the range of the wall in the x-direction (i.e., a direction in which a plurality of first and second electrodes 3, 4 of the IDT electrode 50 is arranged) is shown in FIG. 23. The driving area of the IDT 50 is the region sandwiched by the outermost electrodes of the IDT electrode 50 in the X direction (i.e., the overlapping region 20).

If the average offset distance Lo is an average value of an offset distance of a portion by which the wall 9c of the cavity 9 and the overlapping region 20 overlap in the electrode finger extending direction (i.e., the y-direction in FIG. 23), then the equations Lo≠0 and −Lg<Lo<Lb can be satisfied. That is, if the average offset distance Lo is the distance between the average imaginary straight line 60 and the first inner edge 5a of the first busbar 5, then the equations Lo≠0 and −Lg<Lo<Lb can be satisfied for the upper portion of the cavity 9. Although not shown in FIG. 23, a corresponding average imaginary straight line can also be drawn through the second busbar 6, which can be a corresponding average offset distance Lo from the second inner edge 6a of the second busbar 6 so that the equations Lo≠0 and −Lg<Lo<Lb can be satisfied for the lower portion of the cavity 9.

In general, it is noted that each of the exemplary embodiments described herein is illustrative and that partial substitutions or combinations of configurations are possible among different preferred embodiments. While exemplary embodiments of the present invention have been described above, it is to be understood that variations and modifications will be apparent to those skilled in the art without departing from the scope and spirit of the present invention.

What is claimed:

1. An acoustic wave device comprising:
a support having a cavity therein;
a piezoelectric layer on the support and extending over the cavity; and
an interdigital transducer electrode on the piezoelectric layer and including a pair of busbars that oppose each other and a plurality of electrode fingers extending from the pair of busbars,
wherein d/p is 0.5 or less, where d is a thickness of the piezoelectric layer and p is a distance between centers of a pair of adjacent electrode fingers of the plurality of electrode fingers,
wherein the plurality of electrode fingers extend in an electrode finger extending direction,
wherein the cavity comprises an outer periphery that includes a pair of walls opposed to the electrode finger extending direction in a plan view,
wherein each of the pair of busbars includes an inner edge that faces each other,
wherein the interdigital transducer electrode has an overlapping region in which the plurality of electrode fingers overlap each other when viewed in a direction in which the adjacent electrode fingers are opposed, and a pair of gap regions that are each located between the overlapping region and a corresponding one of the pair of busbars,
wherein the pair of walls of the cavity overlaps, in the plan view, an outer side portion outside the overlapping region in the electrode finger extending direction, and
wherein 0<L<Lb for each of the pair of walls, where Lb is a dimension of each of the pair of busbars in the electrode finger extending direction, and in the plan view, L is a location of each of the pair of walls of the cavity in the electrode finger extending direction.

2. The acoustic wave device according to claim 1, wherein 0<L<(8/25)×Lc in each of the pair of walls, where Lc is a dimension of the overlapping region along the electrode finger extending direction.

3. The acoustic wave device according to claim 1, wherein the support includes:
a support substrate; and
an electrically insulating layer between the support substrate and the piezoelectric layer, and
wherein the cavity extends in the electrically insulating layer.

4. The acoustic wave device according to claim 1, wherein the support includes a support substrate with the cavity disposed therein.

5. The acoustic wave device according to claim 1, wherein the ratio d/p is less than or equal to 0.24.

6. The acoustic wave device according to claim 1, wherein MR≤1.75(d/p)+0.075, where MR is a metallization ratio of an area of the plurality of electrode fingers within the overlapping region to a total area of the overlapping region.

7. An acoustic wave device comprising:
a support that includes a cavity having a first wall and a second wall that oppose each other;
a piezoelectric layer on the support;
an interdigital transducer electrode on the piezoelectric layer and including:
a first bulbar including a first inner edge;
first electrodes extending from the first inner edge, each of the first electrodes including a first non-overlapping portion connected to the first inner edge, and a first overlapping portion connected to the first non-overlapping portion;
a second busbar including a second inner edge facing the first inner edge; and
second electrodes extending from the second inner edge, each of the second electrodes including a second non-overlapping portion connected to the second inner edge, and second overlapping portion connected to the non-overlapping portion and opposed to a corresponding first overlapping portion in an overlapping region,
wherein d/p is 0.5 or less, where d is a thickness of the piezoelectric layer and p is a distance between centers of a pair of adjacent electrodes of the first and the second electrodes,
wherein, in a plan view, the first wall of the cavity is located under the first busbar or the first non-overlapping portion of each of the first electrodes, and
wherein, in the plan view, the second wall of the cavity is located under the second busbar or the second non-overlapping portion of each of the second electrodes.

8. The acoustic wave device of claim 7, wherein 0<L1<(8/25)×Lc, where Lc is a length of the first overlapping portion of each of the first electrodes and the second overlapping portion of each of the second electrodes, and L1 is a distance from the first inner edge to the first wall.

9. The acoustic wave device of claim 8, wherein 0<L2<(8/25)×Lc, where L2 is a distance from the second inner edge to the second wall.

10. The acoustic wave device of claim 7, wherein L1>(1/25)×Lc, where Lc is a length of the first overlapping portion of each of the first electrodes and the second overlapping portion of each of the second electrodes, and L1 is a distance from the first inner edge to the first wall.

11. The acoustic wave device of claim 10, wherein L2>(1/25)×Lc, where L2 is a distance from the second inner edge to the second wall.

12. An acoustic wave device comprising:
a support;
a cavity in the support and including a first wall and a second wall that oppose each other;
a piezoelectric layer on the support;
a first busbar including first electrodes extending from a first inner edge;
a second busbar including second electrodes that extend from a second inner edge and that are interdigitated with the first electrodes;
an overlapping region in which portions of adjacent first and second electrodes oppose each other in a direction perpendicular to which the first and second electrodes extends;
a first gap region that is between the first busbar and the overlapping region and that includes the first electrodes but not the second electrodes; and
a second gap region that is between the second busbar and the overlapping region and that includes the second electrodes but not the first electrodes,
wherein d/p is 0.5 or less, where d is a thickness of the piezoelectric layer and p is a distance between centers of a pair of adjacent electrodes of the first and the second electrodes,
wherein, in a plan view, the first wall of the cavity is located under the first busbar or the first gap region, and
wherein, in the plan view, the second wall of the cavity is located under the second busbar or the second gap region.

13. The acoustic wave device of claim 12, wherein 0<L1<(8/25)×Lc, where Lc is a width of the overlapping region, and L2 is a distance from the first inner edge to the first wall.

14. The acoustic wave device of claim 13, wherein 0<L2<(8/25)×Lc, where L2 is a distance from the second inner edge to the second wall.

15. The acoustic wave device of claim 12, wherein L1>(1/25)×Lc, where Lc is a width of the overlapping region, and L1 is a distance from the first inner edge to the first wall.

16. The acoustic wave device of claim 15, wherein L2>(1/25)×Lc, where L2 is a distance from the second inner edge to the second wall.

17. The acoustic wave device according to claim 12, wherein the support includes:
a support substrate; and
an electrically insulating layer provided between the support substrate and the piezoelectric layer,
wherein the cavity is in the electrically insulating layer.

18. The acoustic wave device according to claim 12, wherein the support includes a support substrate with the cavity disposed therein.

19. The acoustic wave device according to claim 12, wherein d/p is less than or equal to 0.24.

20. The acoustic wave device according to claim 12, wherein MR≤1.75(d/p)+0.075, where MR is a metallization ratio of an area of the first and the second electrodes within the overlapping region to a total area of the overlapping region.
